(19) United States
(12) Patent Application Publication
(10) Pub. No.: US 2015/0254131 A1
(43) Pub. Date: Sep. 10, 2015

(54) MEMORY CONTROLLER, STORAGE DEVICE AND MEMORY CONTROL METHOD

(71) Applicant: Kabushiki Kaisha Toshiba, Minato-ku (JP)

(72) Inventors: Osamu TORII, Setagaya-ku (JP); Kohsuke HARADA, Yokohama-shi (JP)

(73) Assignee: Kabushiki Kaisha Toshiba, Minato-ku (JP)

(21) Appl. No.: 14/445,198

(22) Filed: Jul. 29, 2014

Related U.S. Application Data
(60) Provisional application No. 61/949,548, filed on Mar. 7, 2014.

(51) Int. Cl. G06F 11/10; G11C 29/52

(52) U.S. Cl. CPC G06F 11/1068; G11C 29/52

(57) ABSTRACT

According to one embodiment, there is provided a memory controller that controls nonvolatile memory of K bits/cell, first and second bits of the K bits corresponding to first and second pages, the memory controller including an encoder configured to encode unit data to write in a first page to generate a parity; and a decoder configured to perform an error correction process using the readout unit data and the parity; where readout of the first page is carried out using 2^{K}−1 first voltage values, readout of the second page is carried out using a second voltage value, which is less in number than 2^{K}−1, and a bit value of the second page is selected based on a bit value of the first page of after the error correction.

### CROSS-REFERENCE TO RELATED APPLICATIONS

This application is based upon and claims the benefit of priority from U.S. Provisional Application No. 61/949,548, filed on 7 Mar. 2014; the entire contents of which are incorporated herein by reference.

### FIELD

Embodiments described herein relate generally to a memory controller, a storage device, and a memory control method.

### BACKGROUND

In NAND flash memory (hereinafter referred to as NAND memory), information is stored by the charge amount accumulated at the floating gate of a memory cell. The stored information can be read out as a result of applying voltage (threshold voltage) to the memory cell. In the multi-valued NAND memory, the information of a plurality of bits is stored in a single memory cell, and the information is read out using a plurality of threshold voltages.

### BRIEF DESCRIPTION OF THE DRAWINGS

FIG. 1 is a block diagram illustrating a configuration example of a storage device according to a first embodiment;

FIG. 2 is a view illustrating an electron number distribution in a multi-level cell of two bits/cell and an assigning example of data;

FIG. 3 is a view illustrating one example of an assignment of data value to a distribution of a charge amount of the first embodiment;

FIG. 4 is a view illustrating a charge threshold value for readout of data of a Lower page of the first embodiment;

FIG. 5 is a view illustrating a charge threshold value for readout of data of an Upper page of the first embodiment;

FIG. 6 is a view illustrating a charge threshold value for the readout of the data of the Upper page of the first embodiment;

FIG. 7 is a view illustrating a configuration example of the page data of the first embodiment;

FIG. 8 is a view illustrating a configuration example of the page data of the first embodiment;

FIG. 9 is a view illustrating a configuration example of the page data of the first embodiment;

FIG. 10 is a flowchart illustrating one example of a readout procedure of the Lower page of the first embodiment;

FIG. 11 is a flowchart illustrating one example of a readout procedure of the Upper page of the first embodiment;

FIG. 12 is a view illustrating one example of a voltage level used to determine the bit value of the Upper page; and

FIG. 13 is a view illustrating an electron number distribution and an assigning example of data according to a second embodiment.

### DETAILED DESCRIPTION

In general, according to one embodiment, a memory controller is a memory controller configured to control nonvolatile memory including a memory cell of K bits/cell, the memory controller including an encoder configured to encode unit data to write in a first page to generate a parity, a first bit representing data of the first page and a second bit representing data of a second page among data of K bits; a memory control unit configured to perform control to write the unit data and the parity in the nonvolatile memory; a decoder configured to carry out an error correction process using the unit data and the parity read out from the nonvolatile memory; and a readout control unit configured to give an instruction to carry out readout using 2^{K}−1 first voltage values at time of readout from the first page, and to carry out readout using a second voltage value, which is different from the first voltage value and less than 2^{K}−1, at time of readout from the second page, and select the bit value of the second page from a determination result of the bit value by the second voltage value based on the bit value of after the error correction of the first page.

Exemplary embodiments of a memory controller, a storage device, and a memory control method will be explained below in detail with reference to the accompanying drawings. The present invention is not limited to the following embodiments.

### First Embodiment

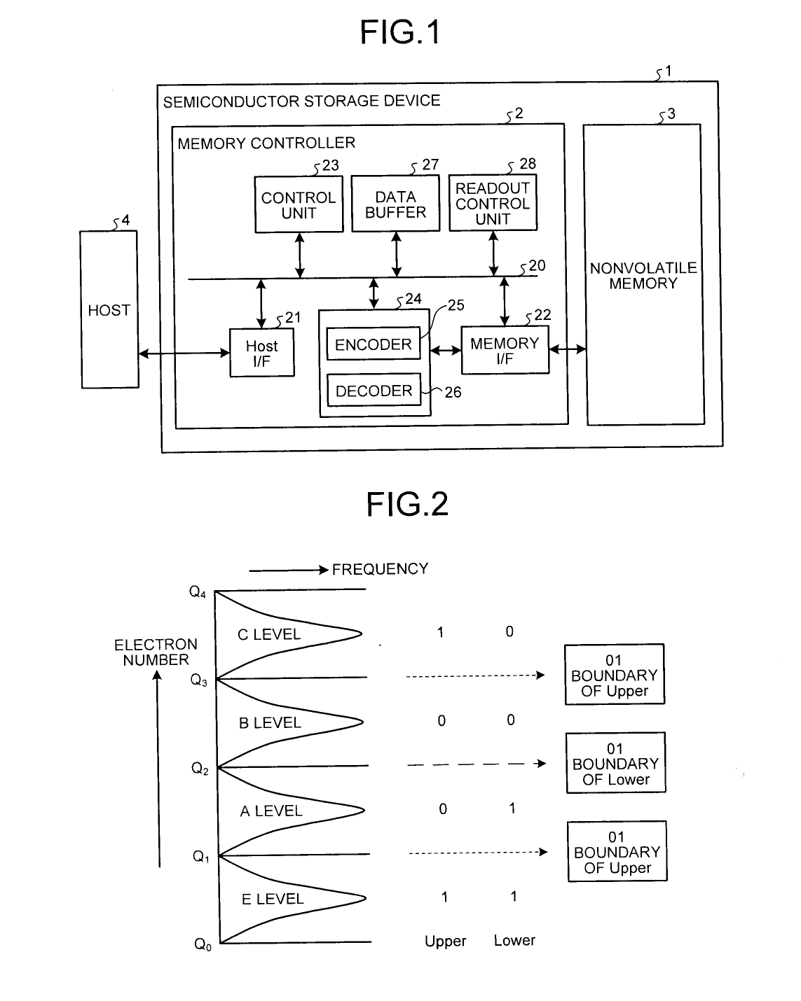

FIG. 1 is a block diagram illustrating a configuration example of a storage device (semiconductor storage device) according to a first embodiment. A semiconductor storage device 1 of the present embodiment includes a memory controller 2 and nonvolatile memory 3. The semiconductor storage device 1 is connectable with a host 4, where a state of being connected to the host 4 is illustrated in FIG. 1. The host 4 is an electronic device such as a personal computer, a portable terminal, and the like, for example.

The nonvolatile memory 3 is nonvolatile memory that stores data in a nonvolatile manner, and is, for example, NAND memory. An example of using the NAND memory for the nonvolatile memory 3 will be described herein, but a memory other than the NAND memory may be adopted. In the NAND memory, write and readout of the data are carried out for every write unit data generally called a page. In the present embodiment, a memory cell of the nonvolatile memory 3 is assumed as a multi-level cell in which two or more bits can be stored in a single memory cell.

The memory controller 2 controls the write in the nonvolatile memory 3 in accordance with a write command from the host 4. The memory controller 2 controls the readout from the nonvolatile memory 3 in accordance with a readout command from the host 4. The memory controller 2 includes a Host I/F 21, a memory I/F 22 (memory control unit), a control unit 23, an ECC (Error Correcting Code) unit 24, a data buffer 27, and a readout control unit 28, which are connected to each other with an internal bus 20.

The Host I/F 21 outputs the command received from the host 4, the user data (write data), and the like to the internal bus 20. The Host I/F 21 transmits the user data read out from the nonvolatile memory 3, the response from the control unit 23, and the like to the host 4.

The memory I/F 22 controls the write process of the user data, and the like to the nonvolatile memory 3 and the readout process of the same from the nonvolatile memory 3 based on an instruction of the control unit 23.

The control unit 23 comprehensively controls the semiconductor storage device 1. The control unit 23 is, for example, a CPU (Central Processing Unit), an MPU (Micro Processing Unit), and the like. When receiving a command from the host 4 via the Host I/F 21, the control unit 23 carries out the control corresponding to such command. For example, the control unit 23 instructs the memory I/F 22 on the write of the user data and the parity in the nonvolatile memory 3 according to the command from the host 4. Furthermore, the control unit 23 instructs the memory I/F 22 on the readout of the user data and the parity from the nonvolatile memory 3 according to the command from the host 4.

The control unit 23 determines a storage region (memory region) on the nonvolatile memory 3 with respect to the user data accumulated in the data buffer 27. The user data are stored in the data buffer 27 via the internal bus 20. The control unit 23 determines the memory region with respect to the data (page data) in units of pages, which is the write unit. In the present specification, the user data stored in one page of the nonvolatile memory 3 is defined as the unit data. If the parity, to be described later, is generated with respect to the unit data, the unit data and the parity are stored in one page of the nonvolatile memory 3 as one page data. In the present embodiment, the parity may not be generated as will be described later, in which case, the unit data is stored in one page of the nonvolatile memory 3 as one page data. The details of the unit data and the parity will be described later. In the present specification, the memory cells commonly connected to one word line are defined as a memory cell group. If the memory cell is a multi-level cell, the memory cell group corresponds to a plurality of pages. For example, if a multi-level cell in which two bits can be stored is used, the memory cell group corresponds to two pages. The control unit 23 determines the memory region of the nonvolatile memory 3 of the write destination for every unit data. A physical address is assigned to the memory region of the nonvolatile memory 3. The control unit 23 manages the memory region of the write destination of the unit data using the physical address. The control unit 23 instructs the memory I/F 22 to specify the determined memory region (physical address) and write the user data in the nonvolatile memory 3. The control unit 23 manages the correspondence of a logical address (logical address managed by the host 4) and the physical address of the user data. When a readout command including the logical address from the host 4 is received, the physical address corresponding to the logical address is specified, and specification of the physical address and the readout of the user data are instructed to the memory I/F 22.

The ECC unit 24 encodes the user data stored in the data buffer 27 to generate the parity. The ECC unit 24 includes an encoder 25 and a decoder 26. The encoder 25 encodes the user data (unit data) to be written to the same page to generate the parity. The parity is written to the page, and the like to where the unit data, which is the basis of encoding, is written. The decoder 26 carries out decoding using the parity. The details of encoding and decoding, and the storage area of the parity according to the present embodiment will be described later.

The data buffer 27 temporarily stores the user data received from the host 4 until storing in the nonvolatile memory 3, or temporarily stores the data read out from the nonvolatile memory 3 until transmitting to the host 4. For example, the data buffer may be configured with a general purpose memory such as SRAM (Static Random Access Memory), DRAM (Dynamic Random Access Memory), and the like.

The readout control unit 28 instructs the memory I/F 22 on the readout voltage (threshold value), the page to read out, and the like based on the type of page to be read out instructed from the control unit 23 at the time of readout from the nonvolatile memory 3. The type of page is the page corresponding to each bit of a plurality of bits stored by the memory cell, and includes Upper page, Lower page, and the like.

In FIG. 1, the configuration example in which the memory controller 2 includes the ECC unit 24 and the memory I/F 22 is illustrated. However, the ECC unit 24 may be incorporated in the memory I/F 22. Alternatively, the readout control unit 28 may be incorporated in the memory I/F 22.

The storage of data in the multi-level cell and the readout method of a comparative example will be described below. FIG. 2 is a view illustrating an electron number distribution in a multi-level cell of two bits/cell and an assigning example of data. In the multi-level cell of two bits/cell, the electrons are injected such that the electron number (charge amount) of the floating gate becomes any one of the four types of distributions according to the data value at the time of the write of the data. In the example of FIG. 2, the four types of distributions are E level (greater than or equal to Q₀ and smaller than Q₁), A level (greater than or equal to Q₁ and smaller than Q₂), B level (greater than or equal to Q₂ and smaller than Q₃), and C level (greater than or equal to Q₃ and smaller than Q₄) in the order of least number of electrons. The data value “11” is corresponded to the E level, the data value “01” is corresponded to the A level, the data value “00” is corresponded to the B level, and the data value “10” is corresponded to the C level. Here, the value of the upper bit of the data values of the two bits stored in the multi-level cell is stored in the Upper page, and the value of the lower bit is stored in the Lower page.

In FIG. 2, an example in which the data value is assigned using a gray code with respect to the four distributions of the charge amount is illustrated. According to such assignment, when reading out the data of the Lower page, whether or not the data of the Lower page is one can be determined from whether or not the charge amount accumulated at the floating gate is greater than or equal to the charge amount Q₂ described as “01 boundary of Lower”. In other words, whether or not the data is one can be determined by applying a voltage (threshold voltage) corresponding to the charge amount Q₂ to the memory cell. Hereinafter, in the present embodiment, the threshold values Q₀ to Q₅ of the charge amount with respect to each level are referred to as charge threshold values, and the voltage for determining whether or not the charge amount accumulated at the floating gate is greater than or equal to the charge threshold values Q₀ to Q₅ is referred to as the threshold voltage.

In the NAND memory, error factors such as data retention error, read disturb error, program disturb failure, and the like are found. Due to such error factors, the charge amount of the floating gate may change and the wrong bit value may be read out at the time of readout from the memory cell. Thus, in the NAND memory, the parity is given so that correction can be made when error occurs. For example, the parity is given to the unit data, and the parity and the unit data are stored in the same page in the nonvolatile memory 3. When using the assigning method of the data value illustrated in FIG. 2, the readout of the page data and the error correction are independently carried out for the Upper page and the Lower page, and the correlation of a plurality of bits stored in the single cell is not taken into consideration. Thus, the error correction that takes into consideration the correlation of the plurality of bits stored in the single cell cannot be carried out. In the present embodiment, on the other hand, the assignment of the data value to the distribution of charge amount and the readout from the nonvolatile memory 3 are carried out in view of the correlation of the plurality of bits as will be described below, whereby the error correction capability can be enhanced.

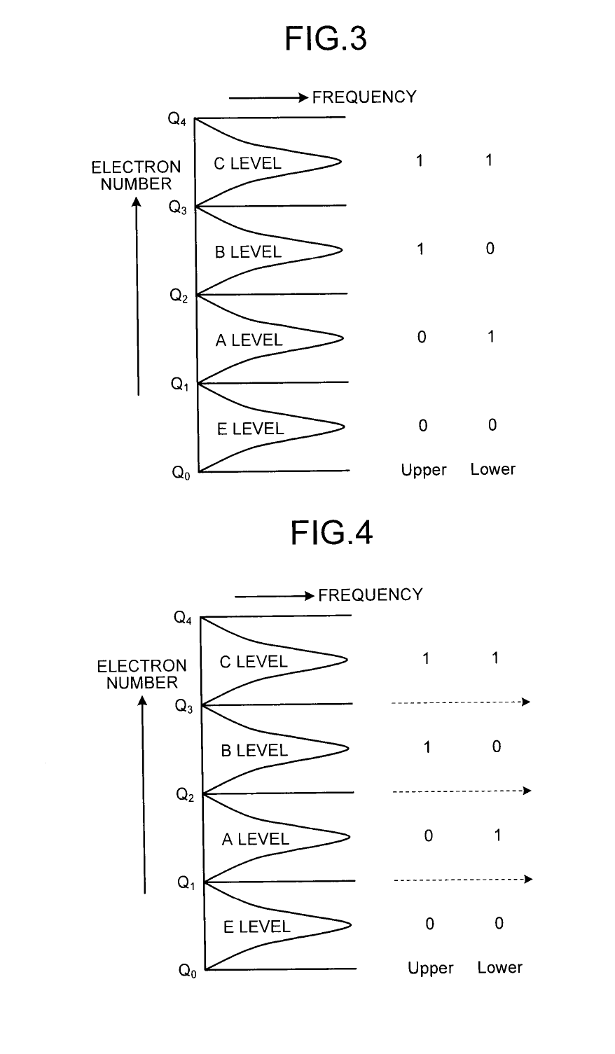

The assigning method of the data value to the distribution of the charge amount and the readout method from the nonvolatile memory 3 according to the present embodiment will be described below. FIG. 3 is a view illustrating one example of the assignment of the data value to the distribution of the charge amount of the present embodiment. As illustrated in FIG. 3, in the present embodiment, the assignment of the data value to the distribution of the charge amount is carried out by a natural code. In other words, the E level, which has the least charge amount, is corresponded to “00”, the A level is corresponded to “01”, the B level is corresponded to “10”, and the C level is corresponded to “11”. In FIG. 3, assignment in which the data value becomes greater with increase in the charge amount is adopted, but the E level may be corresponded to “11”, the A level may be corresponded to “10”, the B level may be corresponded to “01”, and the C level may be corresponded to “00”, opposite to FIG. 3.

FIG. 4 is a view illustrating the charge threshold value for the readout of the data of the Lower page according to the present embodiment. FIG. 4 illustrates, with an arrow of dotted line, the charge threshold value corresponding to the threshold voltage used for the readout of the bit value of the Lower page on the basis of the assignment of the data value illustrated in FIG. 3. The bit value of the Lower page can be read out using three threshold voltages corresponding to Q₁, Q₂, and Q₃ illustrated in FIG. 4. Specifically, three determination results of whether the charge amount is greater than or equal to Q₁, whether the charge amount is greater than or equal to Q₂, and whether the charge amount is greater than or equal to Q₃ are obtained using three threshold voltages, and the bit value of the Lower page can be determined by the three determination results.

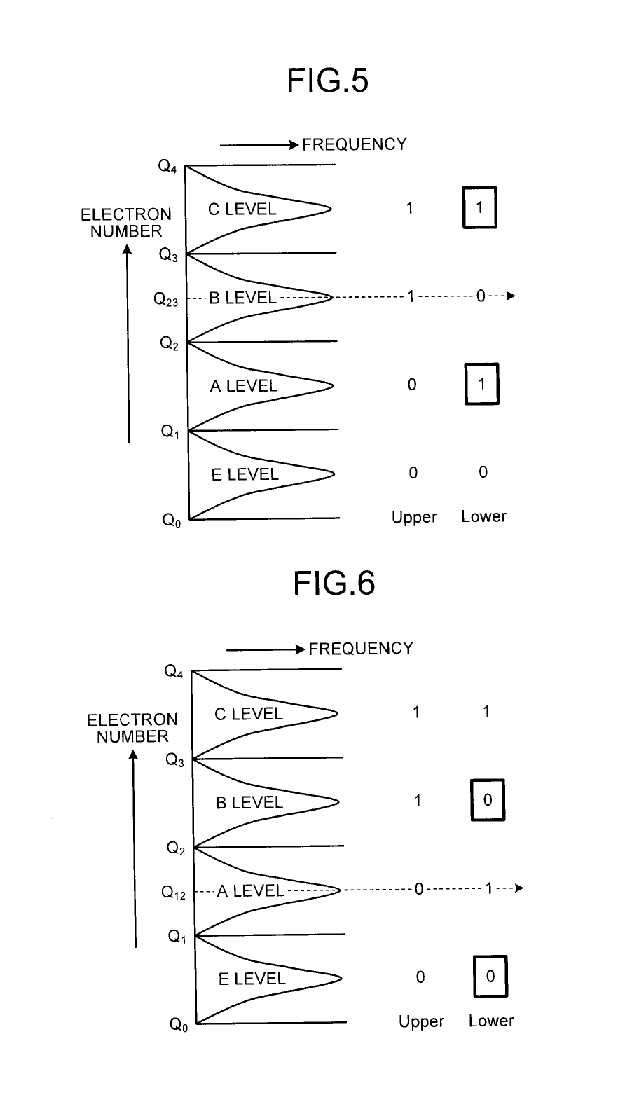

FIGS. 5 and 6 are views illustrating the charge threshold value for the readout of the data of the Upper page according to the present embodiment. FIGS. 5 and 6 illustrate, with an arrow of dotted line, the charge threshold value corresponding to the threshold voltage used in the readout of the data of the Upper page, on the basis of the assignment of the data value illustrated in FIG. 3. FIG. 5 illustrates a case in which the bit value of the Lower page is one, and FIG. 6 illustrates a case in which the bit value of the Lower page is zero.

As illustrated in FIG. 5, when the bit value of the Lower page is “1”, the charge amount accumulated at the floating gate is C level if the Upper page is “1” and A level if the Upper page is “0”. Thus, if the bit value of the Lower page is known to be one, the bit value of the Upper page can be determined by determining whether the A level or the C level. Therefore, as illustrated in FIG. 5, determination can be made using an intermediate charge threshold value Q₂₃ of the charge threshold value Q₂ and the charge threshold value Q₃. The probability a wrong value will be read out at the time of readout can be reduced even if the charge amount of the floating gate is lowered or increased by the error factor. For example, assume that “01” corresponding to the A level is written in the memory cell. Assume that the charge amount of the floating gate of the relevant memory cell increased by about half of the interval of Q₃ and Q₂ due to factors such as read disturb, and the like. In this case, when determination on whether or not greater than or equal to the charge threshold value Q₂ is carried out, the possibility the wrong value will be read out is high. On the contrary, when determination on whether or not greater than or equal to the charge threshold value Q₂₃ is carried out, the possibility the wrong value will be read out lowers compared to when determination on whether or not greater than the charge threshold value Q₂ is carried out.

Similarly, as illustrated in FIG. 6, when the bit value of the Lower page is “0”, the charge amount accumulated at the floating gate is the B level if the Upper page is “1” and the E level if the Upper page is “0”. Thus, determination can be made using an intermediate charge threshold value Q₁₂ of the charge threshold value Q₁ and the charge threshold value Q₂. Thus, the possibility the wrong value will be read out is lowered.

As described above, if the bit value of the Lower page is fixed first, the readout that reduces the readout error of the Upper page can be performed. However, since the bit value of the Lower page has a possibility of including error with the readout bit value as is, the readout of the Upper page is carried out using the bit value of the Lower page of after the error correction using the parity for the Lower page.

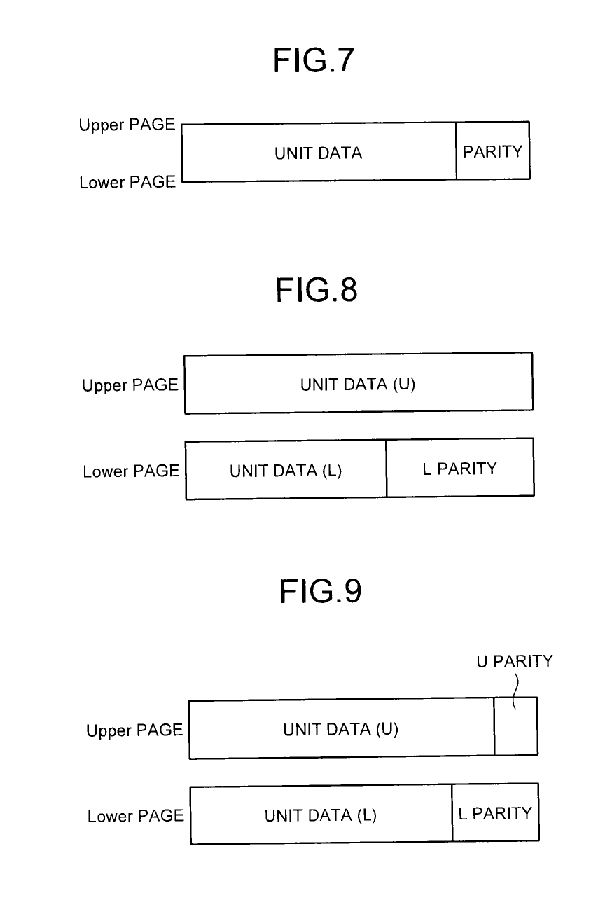

FIGS. 7 to 9 are views illustrating a configuration example of the page data of the present embodiment. In the example of FIG. 7, the parity generated using the unit data stored in each page is stored in the same page as the unit data for the Upper page and the Lower page. As in the example of FIG. 7, the parity of the same size is stored in the Upper page and the Lower page. The example of FIG. 7 is similar to the configuration of the general page data of when independently reading out the Upper page and the Lower page.

In the present embodiment, the probability of the readout error of the Upper page lowers since the readout of the Upper page is carried out based on the bit value of the Lower page, as described above. However, the error at the time of readout cannot be lowered for the Lower page, and hence greater amount of parities than the Upper page are desirably assigned with respect to the Lower page. FIGS. 8 and 9 illustrate an example of assigning greater amount of parities than the Upper page to the Lower page. In FIG. 8, the parity is not added to the user data (U) of the Upper page, and the parity (L parity) is added only to the unit data (L) of the Lower page. The example of FIG. 9 illustrates an example in which the parity (U parity) less than the parity (L parity) of the Lower page is added to the Upper page. According to such configuration, the parity amount associated with the Lower page can be increased with the total (Upper page and Lower page combined) parity amount maintained the same as in FIG. 7. The error correction capability of the Lower page thus can be enhanced. Therefore, for the Lower page, the influence of the readout error is reduced by the parity to enhance the reliability, and the readout of the Upper page is carried out using the threshold voltage corresponding to Q₁₂ and Q₂₃ using the bit value of the Lower page with enhanced reliability. The error correction capability thus can be enhanced.

Other than the examples of FIGS. 8 and 9, for example, the L parity may be divided into two, and stored in a distributed manner to the Upper page and the Lower page. In this case, however, the Upper page also needs to be read out when reading out the Lower page.

The write operation to the nonvolatile memory 3 and the readout operation from the nonvolatile memory 3 according to the present embodiment will now be described. At the time of the write in the nonvolatile memory 3, the unit data and the parity generated using the unit data are written to each memory cell according to the assignment illustrated in FIG. 3.

The operation in readout of the present embodiment differs between the readout of the Upper page and the readout of the Lower page. When the logical address of the data to be read out is instructed from the host 4, the control unit 23 obtains the physical address corresponding to the logical address, and notifies the physical address to the readout control unit 28. In this case, information with which the Upper page and the Lower page can be distinguished is contained as the physical address. Alternatively, the control unit 23 notifies, along with the physical address, the information indicating whether the page corresponding to the relevant physical address is the Upper page or the Lower page to the readout control unit 28.

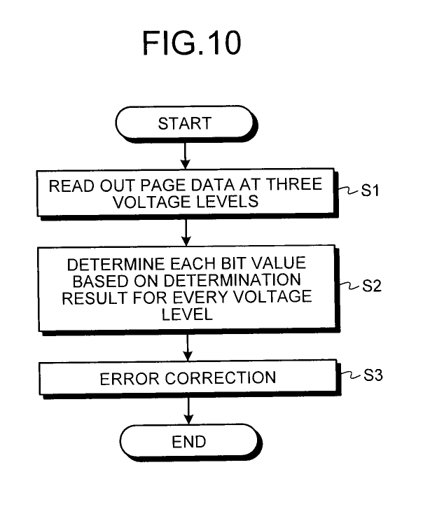

FIG. 10 is a flowchart illustrating one example of a readout procedure of the Lower page of the present embodiment. The readout control unit 28 instructs the nonvolatile memory 3 through the memory I/F 22 to carry out the readout at three voltage levels (voltage levels corresponding to Q₁, Q₂, Q₃ of FIG. 3) with respect to the memory I/F 22 in the case of the readout of the Lower page. The nonvolatile memory 3 carries out the readout at three voltage levels based on the instruction (step S1). The nonvolatile memory 3 then determines the bit value of the Lower page for each memory cell based on the readout results at three voltage levels (results on whether or not the current flowed when the voltage is applied), and outputs to the memory controller 2 (step S2). The decoder 26 performs the error correction process based on the page data (unit data and parity) of the Lower page output from the nonvolatile memory 3 (step S3).

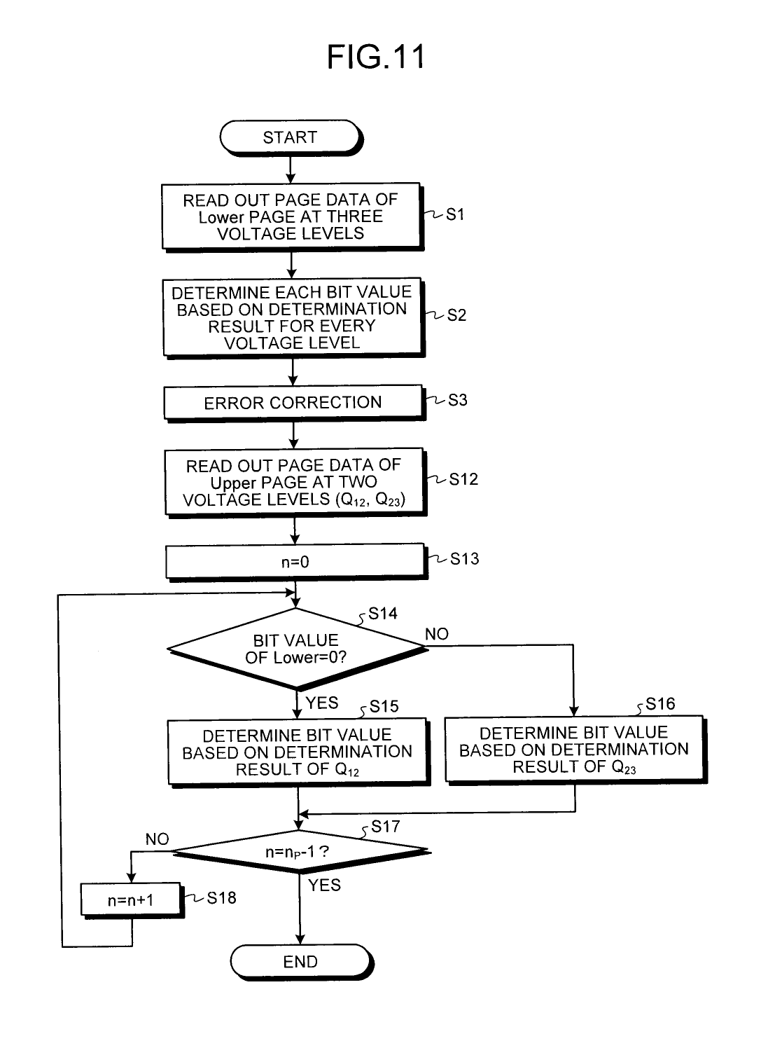

FIG. 11 is a flowchart illustrating one example of the readout procedure of the Upper page of the present embodiment. First, the readout control unit 28 instructs the readout of the Lower page stored in the same memory cell as the Upper page to be read out with respect to the memory I/F 22 in the case of the readout of the Upper page. The steps S1 to S3 of the readout procedure of the Lower page are then performed to read out the page data of the Lower page. The readout control unit 28 instructs the nonvolatile memory 3 through the memory I/F 22 to carry out the readout at two voltage levels (voltage levels corresponding to Q₁₂ and Q₂₃ of FIG. 3). The nonvolatile memory 3 then carries out the readout at two voltage levels based on the instruction, and outputs the determination result of the readout at two voltage levels (bit value determined based on the result of whether or not greater than or equal to the charge threshold value corresponding to the respective voltage level and the bit assignment of FIG. 3) to the memory controller 2 (step S12).

The readout control unit 28 sets a counter n to 0 (step S13), and determines whether or not the bit value of the Lower page of the n^{th} memory cell is “0” (step S14). If the bit value of the Lower page is “0” (Yes in step S14), the bit value of the Upper page of the n^{th} memory cell is determined based on the determination result of the voltage level corresponding to Q₁₂ (step S15). The readout control unit 28 determines whether or not n is nₚ−1 (nₚ is the number of memory cells connected to the same word line) (step S17), and terminates the process if n is nₚ−1 (Yes in step S17). If n is not nₚ−1 (No in step S17), n=n+1 is assumed (step S18), and the process returns to step S14. If the bit value of the Lower page is not “0” (No in step S14), the bit value of the Upper page of the n^{th} memory cell is determined based on the determination result of the voltage level corresponding to Q₂₃ (step S16), and the process proceeds to step S17.

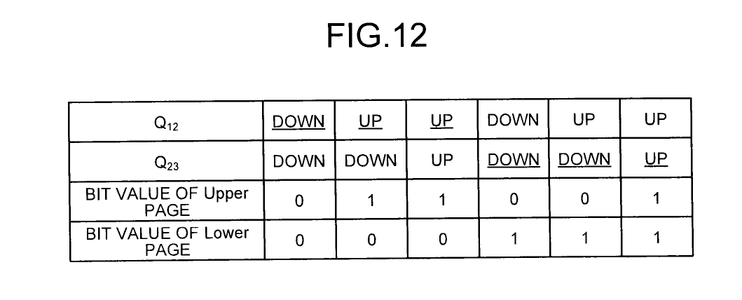

As described above, in the present embodiment, either one of Q₁₂ and Q₂₃ is selected based on the bit value of after the error correction of the Lower page, and the bit value of the Upper page is determined based on the selected threshold value. FIG. 12 is a view illustrating one example of the voltage level used to determine the bit value of the Upper page. The row of Q₁₂ indicates the determination result of the voltage level corresponding to Q₁₂, and the row of Q₂₃ indicates the determination result of the voltage level corresponding to Q₂₃. Each column of FIG. 12 corresponds to each memory cell, and the row of the bit value of the Lower page indicates the bit value of the Lower page after the error correction. The underlined bit value is the bit value of the Upper page determined with the readout procedure described above.

In the above description, an example of carrying out the assignment by the natural code has been described as illustrated in FIG. 3. However, the present embodiment can be applied without limiting to the natural code as long as an assigning method, in which the bits of the Lower page are lined such that 1 and 0 are alternately repeated and in which the boundary position of 0 and 1 of the Upper page can be changed using the fixed result of the bit value of the Lower page, is adopted.

As described above, in the present embodiment, the bit assignment by the natural code is carried out with respect to the charge amount distribution, and the charge threshold values Q₁₂ and Q₂₃ different from the normal charge threshold value to become the boundary of the charge amount distribution are defined. At the time of the readout of the Lower page (first page), the readout is carried out at three voltage levels, which are the normal charge threshold values to become the boundary of the charge amount distribution. At the time of the readout of the Upper page (second page), the Lower page is read out and error corrected, and either one of the charge threshold values Q₁₂ and Q₂₃ different from the boundary of the charge amount distribution is selected based on the bit value of the Lower page of after the error correction to determine the bit value of the Upper page. Thus, for the Upper page, the bit value is determined using the charge threshold values Q₁₂ and Q₂₃, and hence error due to the movement of the charge amount distribution is less likely to occur. A greater amount of parity than the Upper page thus can be assigned to the Lower page, and the error correction capability as a whole can be enhanced.

Generally, the Lower page and the Upper page corresponding to the memory cell connected to the same word line are often continuously performed with write, and the Lower page and the Upper page are also often continuously read out in readout. Therefore, when the Lower page is read out, the data (after error correction) of the Lower page is saved in the data buffer 27, and the like for a constant period so that steps S1 to S3 of FIG. 11 do not need to be performed and the lowering in the readout speed can be prevented when carrying out the readout of the corresponding Upper page.

### Second Embodiment

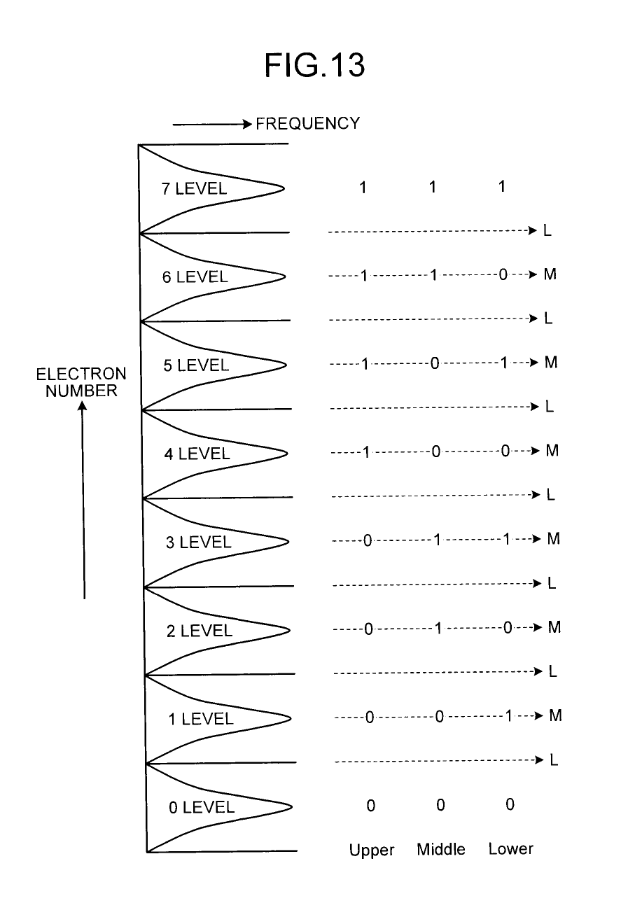

FIG. 13 is a view illustrating an electron number distribution and an assigning example of the data according to a second embodiment. The configuration of the semiconductor storage device 1 according to the present embodiment is similar to the first embodiment. A portion different from the first embodiment will be hereinafter described below.

Nonvolatile memory 3 of the present embodiment includes a memory cell of three bits/cell. The present embodiment carries out assignment by the natural code, similar to the first embodiment, with respect to the memory cell of three bits/cell. The dotted line described as L on the right side of the figure is the charge threshold value used when reading out the Lower page, and the dotted line described as M on the right side is the charge threshold value used when reading out the Middle page.

At the time of write in the nonvolatile memory 3, the unit data and the parity generated using the unit data are written to each memory cell according to the assignment illustrated in FIG. 13.

The operation at the time of readout of the Lower page of the present embodiment is similar to the operation at the time of readout of the Lower page of the first embodiment other than that there are seven voltage levels to use in the readout. Similar to the operation at the time of the readout of the Upper page of the first embodiment, the operation of the readout of the Middle page according to the present embodiment selects the charge threshold value to use in the determination of the bit value of the Middle page based on the bit value of after the error correction of the Lower page, and determines the bit value of the Middle page using the selected charge threshold value.

Specifically, if the bit value of after the error correction of the Lower page is zero, the readout is performed at three voltage levels respectively corresponding to the vicinity of the vertices of the three charge threshold values of 1 level, 3 level, and 5 level. If the bit value of after the error correction of the Lower page is one, the readout is performed at three voltage levels respectively corresponding to the vicinity of the vertices of the three charge threshold values of 2 level, 4 level, and 6 level. Actually, the readout may be carried out at six voltage levels respectively corresponding to the vicinity of the six vertices of 1 to 6 levels, and then the readout result of the three voltage levels may be respectively referenced. The bit value of the Middle page is determined based on the readout result of the three voltage levels (whether or not the charge amount of the floating gate is greater than or equal to the respective charge threshold value for the three charge threshold values).

For example, when the bit value of the Lower page is 0, the bit value of the Middle page is 1, and the bit value of the Upper page is 0, the charge distribution of 2 level is the ideal distribution. If the bit value of the Lower page is fixed at 0, and the readout is carried at three voltage levels corresponding to the three charge threshold values of 1 level, 3 level, 5 level in this case, the determination results respectively become “up”, “down”, and “down”. “Up” in the determination result is the determination result in which the charge amount of the floating gate is greater than or equal to the charge threshold value, and “down” is the determination result in which the charge amount of the floating gate is smaller than the charge threshold value. According to such determination results, the bit value of the Middle page can be fixed as 1. When the charge distribution that ideally becomes 2 level is shifted to the upper side, for example, error may possibly occur if the readout is carried out at the voltage level corresponding to the charge threshold value between 2 level and 3 level, but the accuracy of the readout becomes high if the readout is carried out at the voltage level corresponding to the charge threshold value in the vicinity of the vertex of 3 level.

The operation of the readout of the Upper page of the present embodiment includes determining the bit value of the Middle page described above, and then selecting the charge threshold value to use in the determination of the bit value of the Upper page based on the bit values of the Lower page and the Middle page, and determining the bit value of the Upper page using the selected charge threshold value. When the bit value of the Lower page is fixed at 0 and the bit value of the Middle page is fixed at 0, the bit value of the Upper page is determined using the determination result of the readout at the voltage level corresponding to the vicinity of the vertex of 2 level. When the bit value of the Lower page is fixed at 0 and the bit value of the Middle page is fixed at 1, the bit value of the Upper page is determined using the determination result of the readout at the voltage level corresponding to the vicinity of the vertex of 4 level. When the bit value of the Lower page is fixed at 1 and the bit value of the Middle page is fixed at 0, the bit value of the Upper page is determined using the determination result of the readout at the voltage level corresponding to the vicinity of the vertex of 3 level. When the bit value of the Lower page is fixed at 1 and the bit value of the Middle page is fixed at 1, the bit value of the Upper page is determined using the determination result of the readout at the voltage level corresponding to the vicinity of the vertex of 5 level. As apparent from FIG. 13, if the determination of the bit value of the Upper page is shifted to the upper side or the lower side from the boundary (value of 3 level and 4 level) of the bit value of the Upper page, the readout accuracy becomes higher by carrying out the determination at the boundary (value of 3 level and 4 level) of the bit value of the Upper page. Thus, the voltage level to use in the determination of the bit value of the Upper page is not limited to the example described above.

According to the example described above, in the readout of the Upper page, the bit value is determined in the order of the Lower page and the Middle page, and then the bit value of the Upper page is determined. In other words, the bit value is determined in the order of the Lower page (first page), Middle page (second page), and Upper page (third page), but the bit value of the Upper page (second page) may be determined based on the bit value of the Lower page (first page) without reading out the Middle page. In this case, there are two charge threshold values to use in the readout of the Upper page, the intermediate value (assumed as U1) of the charge threshold value third from the top of the Upper page and the charge threshold value fourth from the top of the Upper page, and the intermediate value (assumed as U2) of the charge threshold value fourth from the top of the Upper page and the charge threshold value fifth from the top of the Upper page. The result of the determination on which of the eight charge distributions is realized in the readout of the Lower page is output from the nonvolatile memory 3. If the charge distribution is one of the three (7 level, 6 level, 5 level) from the top, the bit value of the Upper page is determined as “1” regardless of the readout result of the Upper page. If the charge distribution is one of the three (2 level, 1 level, 0 level) from the bottom, the bit value of the Upper page is determined as “0” regardless of the readout result of the Upper page. If determined that the charge distribution is the fourth or the fifth (4 level or 3 level) from the top in the readout of the Upper page, the determination result of U1 is selected if the bit value of the Lower page is “0” and the determination result of U2 is selected if the bit value is “0” of the two readout results of the Upper page.

When determining the bit value of the Upper page based on the bit value of the Middle page without reading out the Lower page, the readout is first carried out using three charge threshold values, which are second, fourth and sixth from the top, of the charge threshold values used in reading out the Lower page of FIG. 13 to determine the bit value. The readout of the Upper page is carried out using two charge threshold values, which are the third charge threshold value and the fifth charge threshold value from the top, of the charge threshold values used in reading out the Lower page of FIG. 13, and the charge threshold value is selected from the two charge threshold values based on the bit value of the Middle page of after the error correction.

In the present embodiment, it is desirable that the greatest amount of parities are added to the Lower page, and the least amount of parities are added (or parity is not added) to the Upper page.

In the present embodiment, therefore, for the case of three bits/cell, the bit assignment by the natural code is carried out with respect to the charge amount distribution, and the charge threshold value different from the normal charge threshold value to become the boundary of the charge amount distribution is defined. At the time of the readout of the Upper page, the readout and the error correction of the Lower page, and the readout and the error correction of the Middle page are carried out, and then the charge threshold value different from the boundary of the charge amount distribution is selected based on the bit value of the Middle page of after the error correction to determine the bit value of the Upper page.

The two bits/cell has been described in the first embodiment, and the three bits/cell has been described in the second embodiment. In summary, when carrying out the assignment by the natural code, the number of charge threshold values for the readout of the Lower page is 2^{K}−1 for the case of K (K is an integer greater than or equal to two) bits/cell. At the time of the readout of the Lower page, the readout is carried out using 2^{K}−1 voltage levels (first voltage value). At the time of the readout of a page other than the Lower page, the readout is carried out at P (P<2^{K}−1) voltage levels (second voltage level) different from the 2^{K}−1 voltage levels, and the voltage level to use in the determination of the bit value of the page to be read out is selected based on the bit value of the Lower page. Similar readout method can be applied for the case in which K is greater than or equal to four.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory controller configured to control nonvolatile memory including a memory cell in which data of K bits is storable in one memory cell, where K is an integer greater than or equal to two, a first bit of the data of K bits representing data of a first page and a second bit representing data of a second page, the memory controller comprising:
an encoder configured to encode unit data to write in the first page to generate a parity;
a memory control unit configured to perform control to write the unit data and the parity in the nonvolatile memory at time of write in the first page, and to perform control to write the unit data in the nonvolatile memory at time of write in the second page;
a decoder configured to perform an error correction process using the unit data and the parity read out from the nonvolatile memory; and
a readout control unit configured to instruct the memory control unit to carry out readout using 2^{K}−1 first voltage values at time of readout from the first page and instruct the memory control unit to carry out readout using a second voltage values, which are different from the first voltage value and less in number than 2^{K}−1, at time of readout from the second page, and to select a bit value of the second page from a determination results of the bit value by the second voltage values based on the bit value of after the error correction of the first page; wherein the memory control unit performs the readout from the nonvolatile memory based on an instruction from the readout control unit.

2. The memory controller according to claim 1, wherein
K=2; and
the second voltage value is an intermediate value of the largest first voltage value and the second largest first voltage value, and an intermediate value of the second largest first voltage value and the third largest first voltage value.

3. The memory controller according to claim 1, wherein
K=2;
the encoder encodes the unit data to write in the second page to generate a parity;
the memory control unit performs the control to write the unit data and the parity in the nonvolatile memory at the time of the write in the second page; and
the decoder carries out the error correction process based on the unit data and the parity of the second page determined based on the bit value of the first page.

4. The memory controller according to claim 1, wherein
K=3; and
the second voltage value includes an intermediate value of one of the first voltage values and the first voltage value next largest to the one first voltage value.

5. The memory controller according to claim 1, wherein
K=3;
a third bit of the data of K bits represents data of a third page; and
the readout control unit instructs the memory control unit to carry out the readout using a third voltage value, which is different from the first voltage value and less in number than 2^{K}−1, at time of readout from the third page, and selects a bit value of the third page from a determination result of the bit value by the third voltage value based on the bit value of the second page determined based on the bit value of the first page.

6. The memory controller according to claim 5, wherein
the encoder encodes the unit data to write in the second page to generate a parity;
the memory control unit performs the control to write the unit data and the parity in the nonvolatile memory at the time of write in the second page;
the decoder carries out an error correction process based on the unit data and the parity of the second page determined based on the bit value of the first page; and
a fixed bit value of the second page is the bit value of the second page of after the error correction process.

7. The memory controller according to claim 1, wherein
K=3;
a third bit of the data of K bits represents data of a third page; and
the readout control unit instructs the memory control unit to carry out the readout using a third voltage value, which is different from the first voltage value and less in number than 2^{K}−1, at the time of readout from the third page, and selects a bit value of the third page from a determination result of the bit value by the third voltage value based on the bit value of after the error correction of the first page.

8. The memory controller according to claim 1, wherein an assignment of the bit value with respect to 2^{K} charge amount distributions of the memory cell is an assignment in which a bit value to be assigned to the charge amount distribution is incremented by one bit in an order of large charge amount or small charge amount.

9. A storage device comprising:
nonvolatile memory including a memory cell in which data of K bits is storable in one memory cell, where K is an integer greater than or equal to two, a first bit of the data of K bits representing data of a first page and a second bit representing data of a second page; and
a memory controller configured to control the nonvolatile memory, wherein
the memory controller includes,
an encoder configured to encode unit data to write in the first page to generate a parity,
a memory control unit configured to perform control to write the unit data and the parity in the nonvolatile memory at time of write in the first page, and to perform control to write the unit data in the nonvolatile memory at time of write in the second page;
a decoder configured to perform an error correction process using the unit data and the parity read out from the nonvolatile memory, and
a readout control unit configured to instruct the memory control unit to carry out readout using 2^{K}−1 first voltage values at time of readout from the first page and instruct the memory control unit to carry out readout using a second voltage values, which are different from the first voltage value and less in number than 2^{K}−1, at time of readout from the second page, and to select a bit value of the second page from a determination results of the bit value by the second voltage values based on the bit value of after the error correction of the first page; and
the memory control unit performs the readout from the nonvolatile memory based on an instruction from the readout control unit.

10. The storage device according to claim 9, wherein
K=2; and
the second voltage value is an intermediate value of the largest first voltage value and the second largest first voltage value, and an intermediate value of the second largest first voltage value and the third largest first voltage value.

11. The storage device according to claim 9, wherein
K=2;
the encoder encodes the unit data to write in the second page to generate a parity;
the memory control unit performs the control to write the unit data and the parity in the nonvolatile memory at the time of the write in the second page; and
the decoder carries out the error correction process based on the unit data and the parity of the second page determined based on the bit value of the first page.

12. The storage device according to claim 9, wherein
K=3; and
the second voltage value includes an intermediate value of one of the first voltage values and the first voltage value next largest to the one first voltage value.

13. The storage device according to claim 9, wherein
K=3;
a third bit of the data of K bits represents data of a third page; and
the readout control unit instructs the memory control unit to carry out the readout using a third voltage value, which is different from the first voltage value and less in number than 2^{K}−1, at time of readout from the third page, and selects a bit value of the third page from a determination result of the bit value by the third voltage value based on the bit value of the second page determined based on the bit value of the first page.

14. The storage device according to claim 13, wherein
the encoder encodes the unit data to write in the second page to generate a parity;
the memory control unit performs the control to write the unit data and the parity in the nonvolatile memory at the time of write in the second page;
the decoder carries out an error correction process based on the unit data and the parity of the second page determined based on the bit value of the first page; and
a fixed bit value of the second page is the bit value of the second page of after the error correction process.

15. The storage device according to claim 9, wherein
K=3;
a third bit of the data of K bits represents data of a third page; and
the readout control unit instructs the memory control unit to carry out the readout using a third voltage value, which is different from the first voltage value and less in number than 2^{K}−1, at the time of readout from the third page, and selects a bit value of the third page from a determination result of the bit value by the third voltage value based on the bit value of after the error correction of the first page.

16. The storage device according to claim 9, wherein an assignment of the bit value with respect to 2^{K} charge amount distributions of the memory cell is an assignment in which a bit value to be assigned to the charge amount distribution is incremented by one bit in an order of large charge amount or small charge amount.

17. A memory control method for controlling nonvolatile memory including a memory cell in which data of K bits is storable in one memory cell, where K is an integer greater than or equal to two, a first bit of the data of K bits representing data of a first page and a second bit representing data of a second page, the memory control method comprising:
encoding unit data to write in the first page, and generating a parity;
controlling to write the unit data and the parity in the nonvolatile memory at time of write in the first page, and controlling to write the unit data in the nonvolatile memory at time of write in the second page;
performing an error correction process using the unit data and the parity read out from the nonvolatile memory;
carrying out readout using 2^{K}−1 first voltage values at time of readout from the first page; and
carrying out readout using a second voltage values, which are different from the first voltage values and less in number than 2^{K}−1, at time of readout from the second page, and selecting a bit value of the second page from a determination results of the bit value by the second voltage values based on the bit value of after the error correction of the first page.
